(19) United States
(12) Patent Application Publication
(10) Pub. No.: US 2011/0277824 A1
(43) Pub. Date: Nov. 17, 2011

(54) Solar Cell and Method of Manufacturing the Same

(75) Inventors: Hyun Woo Lee, Seoul (KR); Hae Seok Lee, Yongin-si (KR); Eun Joo Lee, Seongnam-si (KR); Jun Young Choi, Siheung-si (KR); Dong Joon Oh, Busan (KR); Ji Myung Shim, Incheon (KR); Kyeong Yeon Cho, Yongin-si (KR); Ji Sun Kim, Seoul (KR); Il Hwan Kim, Cheongju-si (KR); Jung Eun Shin, Yeosu-si (KR)

(73) Assignee: SHIN SUNG HOLDINGS CO., LTD., Seongnam-si (KR)

(21) Appl. No.: 13/106,103

(22) Filed: May 12, 2011

(30) Foreign Application Priority Data
May 17, 2010 (KR) 10-2010-0045922

(51) Int. Cl. H01L 31/02; H01L 31/18

(52) U.S. Cl. 136/252; 438/72; 257/E31.127

(57) ABSTRACT

Provided are a solar cell and a method of manufacturing the same. The method includes implanting impurities of a second conductivity type opposite to a first conductivity type into a front surface of a semiconductor substrate of the first conductivity type to form an emitter layer, forming a mask layer on the emitter layer, patterning the mask layer by coating etching paste on a portion of the mask layer where a front electrode will be formed, implanting high-concentration impurities into the portion of the mask layer where the front electrode will be formed to form a heavily doped region, removing the remaining mask layer, forming an anti-reflective coating (ARC) on the emitter layer, forming the front electrode on the front surface of the semiconductor substrate, and forming a rear electrode on a rear surface of the semiconductor substrate. In the method of manufacturing the solar cell, the patterning of the front surface of the semiconductor substrate includes directly coating a corrosive emulsion on the mask layer using a screen printing process instead of complicated photolithography and etching processes so that a desired pattern can be formed using a relatively simple process.

### CROSS-REFERENCE TO RELATED APPLICATION

This application claims priority to and the benefit of Korean Patent Application No. 2010-0045922, filed on May 17, 2010, the disclosure of which is incorporated herein by reference in its entirety.

### BACKGROUND

1. Field of the Invention

The present invention relates to a solar cell and a method of manufacturing the same, and more particularly, to a solar cell and a method of fabricating the same, which may facilitate the patterning of a front surface of a semiconductor substrate of the solar cell.

2. Discussion of Related Art

As a forecast of the exhaustion of conventional energy resources, such as petroleum or coal, has been made, alternative energy sources to replace conventional energy resources have lately attracted more attention. Among the alternative energy sources, solar cells are being watched with keen interest because required energy sources are abundant and environmental pollution is hardly caused. Solar cells may be categorized as solar heat cells configured to generate vapor required to rotate turbines, or solar light cells configured to convert photons into electric energy using the properties of a semiconductor. Typically, solar cells may refer to solar light cells (hereinafter, inclusively referred to as “solar cells”).

FIG. 1 is a schematic view showing a basic structure of a solar cell.

Referring to FIG. 1, like a diode, the solar cell may have a junction between a p-type semiconductor layer 101 and an n-type semiconductor layer 102. When light is incident to the solar cell, electrons carrying negative (−) electric charges and holes carrying positive (+) electric charges obtained by emitting the electrons may be generated due to interaction between the light and materials of the p-type and n-type semiconductor layers 101 and 102, and move to enable the flow of current. This phenomenon is called a photovoltaic effect. In the p-type and n-type semiconductor layers 101 and 102 of the solar cell, the electrons and holes may be attracted toward the n-type and p-type semiconductor layers 102 and 101, respectively, and move to electrodes 103 and 104 bonded with the n-type and p-type semiconductor layers 101 and 102, respectively. By connecting the electrodes 103 and 104 using electric wires, electricity may flow to generate electric power.

Meanwhile, to reduce electrical loss of a solar cell, a lightly doped emitter having a high sheet resistance may be applied to the solar cell so as to reduce surface recombination, and a portion where an electrode is bonded with a substrate may be heavily doped so as to minimize a serial resistance between the electrode and the substrate. The above-described structure may be referred to as a selective emitter structure, which may increase the absorptivity of light energy in a short wavelength range corresponding to a blue response range, and improve the photoelectric conversion efficiency of the solar cell.

To provide confined fine etching patterns/structures, such as buried structures, in the industries of photovoltaics, electronics, and semiconductors, material-intensive, time-consuming, and costly process operations may be required prior to an etching operation. For example, a known photolithographic masking process may be required before an actual etching operation.

In the photolithographic masking process, a silicon (Si) wafer may be used as a substrate, and a high-density oxide layer may be formed on the silicon wafer using a thermal oxidation process to obtain the following structure. More specifically, the silicon wafer may be coated with photoresist, dried, and exposed to ultraviolet (UV) light using a photomask. Thereafter, an oxide may be stripped from a target point using a developing process, and removed using fluoric acid. In this case, the remaining photoresist may be subsequently removed using, for example, a solvent. The above-described process may be referred to as a “stripping process”.

A portion of the silicon wafer having an oxide mask, which is not covered with the oxide, may be selectively etched due to strong base, for example 30% potassium hydroxide (KOH). That is, since the oxide mask has tolerance to a base, after the uncovered portion of the silicon wafer is selectively etched, the oxide mask may be typically removed again using fluoric acid.

The above-described lithography processes are not used in industrial manufacture of solar cells because of costs. However, it is necessary to selectively structure and open a silicon surface or layer due to the following operations.

A high-priced process for forming a selective emitter may conventionally be performed using a lithography oxide. A wafer may be masked with the lithography oxide to intactly leave a region where a contact will be formed. Phosphorus (P) ions may be diffused into the masked wafer so that an unmasked region can be n++-doped. Also, after removing the oxide mask, the entire wafer may be n+-doped.

Thus, a selective emitter having a heavily n++-type-doped region with a dopant concentration of about 1×10²⁰ cm⁻³ with respect to a solar cell and a depth of about 2 to 3 μm, and a planar n+-type-doped emitter with a dopant concentration of about 1×10¹⁹ cm⁻³ with respect to the entire solar cell are provided.

In conventional manufacture of solar cells, an alternative method to a lithography process may be to use a contact line screen-printed as an etch mask as disclosed in documents associated with conventional wet and plasma chemical etching processes. A conventional method of dipping a screen-printed solar cell in a mixture of hydrogen fluoride (HF) and nitric acid (HNO₃) may attack silicon disposed directly under metal contact lines in addition to the removal of silicon between the metal contact lines, and inflict etching damage on the metal contact lines. As a result, fill factor may be sharply reduced.

### SUMMARY OF THE INVENTION

The present invention is directed to a solar cell and a method of manufacturing the same, which may reduce consumption of an etchant and minimize material loss of the solar cell using inexpensive etching paste rapidly and selectively applicable to an etch region so that material loss and manufacturing costs required for p-n transition opening of the solar cell can be reduced.

Also, the present invention is directed to a solar cell and a method of manufacturing the same, which may enable easy patterning of a front surface of a semiconductor substrate of the solar cell.

Furthermore, the present invention is directed to a solar cell and a method of manufacturing the same, which may reduce surface recombination and a serial resistance of an electrode and a substrate using a selective emitter to enhance photoelectric conversion efficiency.

According to an aspect of the present invention, there is provided a method of fabricating a solar cell, including implanting impurities of a second conductivity type opposite to a first conductivity type into a front surface of a semiconductor substrate of the first conductivity type to form an emitter layer, forming a mask layer on the emitter layer, patterning the mask layer by coating etching paste on a portion of the mask layer where a front electrode will be formed, implanting high-concentration impurities into the portion of the mask layer where the front electrode will be formed to form a heavily doped region, removing the remaining mask layer, forming an anti-reflective coating (ARC) on the emitter layer, forming the front electrode on the front surface of the semiconductor substrate, and forming a rear electrode on a rear surface of the semiconductor substrate.

The patterning of the mask layer may be performed by coating the etching paste using a printing process.

The etching paste may contain an acid etching medium.

The formation of the mask layer may be performed using a thermal growing process.

The formation of the mask layer may be performed using a thermal growing process at a temperature of about 900° C.

The thermal growing process may include a wet growing process and a dry growing process.

The formation of the mask layer may be performed using a deposition process.

The deposition process may be performed using a plasma-enhanced chemical vapor deposition (PECVD) process.

The deposition process may be performed using a deposition gas containing monosilane (SiH₄).

The formation of the ARC may be performed using a thermal growing process.

The formation of the ARC may be performed using a thermal growing process at a temperature of about 900° C.

The thermal growing process may include a wet growing process and a dry growing process.

The formation of the ARC may be performed using a deposition process.

The deposition process may be performed using a PECVD process.

The deposition process may be performed using a deposition gas containing SiH₄.

The ARC may contain SiNₓ.

The ARC may have a refractive index of 2.0 to 2.3.

The formation of the front and rear electrodes on front and rear surfaces of the semiconductor substrate may be performed using a printing process.

The rear electrode of the semiconductor substrate may be formed using aluminum (Al).

The formation of the rear electrode of the semiconductor substrate may include coating aluminum on the rear surface of the semiconductor substrate and forming a back-surface field (BSF) layer by annealing the aluminum.

According to another aspect of the present invention, there is provided a solar cell manufactured using the above-described method.

### BRIEF DESCRIPTION OF THE DRAWINGS

The above and other objects, features and advantages of the present invention will become more apparent to those of ordinary skill in the art by describing in detail exemplary embodiments thereof with reference to the accompanying drawings, in which:

FIG. 1 is a schematic view showing a basic structure of a solar cell; and

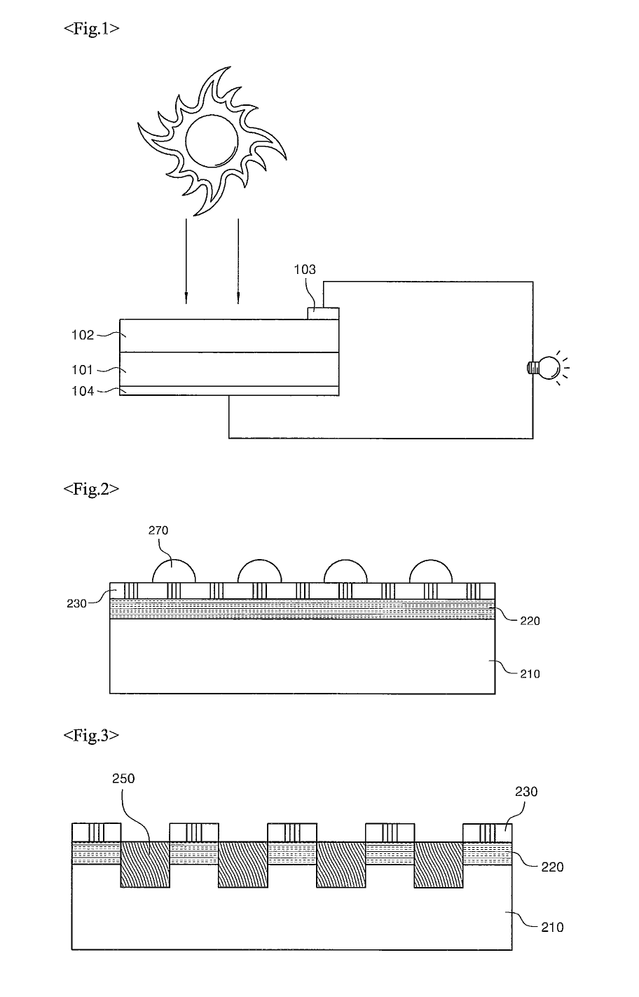

FIGS. 2 through 4 are cross-sectional views illustrating a process of manufacturing a solar cell according to an exemplary embodiment of the present invention.

### DETAILED DESCRIPTION OF EXEMPLARY EMBODIMENTS

Exemplary embodiments of the present invention will be described in detail below with reference to the accompanying drawings. While the present invention is shown and described in connection with exemplary embodiments thereof, it will be apparent to those skilled in the art that various modifications can be made without departing from the spirit and scope of the invention. To facilitate understanding, identical reference numerals have been used, where possible, to designate identical elements that are common to the figures. Descriptions of well-known components and processing techniques are omitted so as not to unnecessarily obscure the embodiments of the present invention.

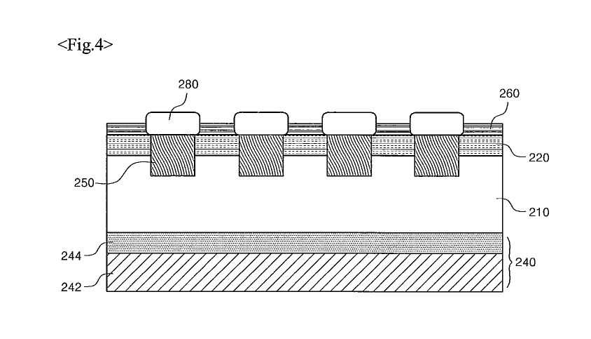

FIGS. 2 through 4 are cross-sectional views illustrating a process of manufacturing a solar cell according to an exemplary embodiment of the present invention.

Referring to FIG. 2, impurities of a second conductivity type opposite to a first conductivity type may be implanted into a front surface of a semiconductor substrate 210 of the first conductivity type, thereby forming an emitter layer 220. According to an embodiment, the semiconductor substrate 210 may be formed of p-type crystalline silicon and lightly doped with phosphorus (P) ions to form the emitter layer 220.

Thereafter, a mask layer 230 may be formed on the emitter layer 220. According to an embodiment, the mask layer 230 may be formed of SiO₂.

According to an embodiment, the mask layer 230 may be formed using a thermal growing process. In an embodiment, the mask layer 230 may be formed using a thermal growing process at a temperature of about 900° C. In an embodiment, the thermal growing process for forming the mask layer 230 may include a wet growing process and a dry growing process.

According to another embodiment, the mask layer 230 may be formed using a deposition process. In the present invention, the deposition process may be performed using a plasma-enhanced chemical vapor deposition (PECVD) process. In this case, the deposition process may be performed using a deposition gas containing monosilane (SiH₄).

Next, a portion of the mask layer 230 where a front electrode will be formed may be patterned. In the present invention, the mask layer 230 may be patterned using an etching process of etching the portion of the mask layer 230 where the front electrode will be formed. In this case, the etching process may be performed using an etchant containing a polymer organic material.

FIG. 2 is a cross-sectional view showing a patterning process of coating etching paste 270 on the portion of the mask layer 230 where the front electrode will be formed. In an embodiment, the etching paste 270 may be coated using a printing process. Also, in an embodiment, the etching paste 270 may contain an acid etching medium.

Referring to FIG. 3, high-concentration impurities may be implanted into a portion of the emitter layer 220 where the front electrode will be formed, thereby forming a heavily doped region 250. Thus, a sheet resistance of the emitter layer 220 may be increased to reduce recombination, and a portion where the front electrode is bonded with the semiconductor substrate 210 may be heavily doped to provide a selective emitter structure capable of minimizing a serial resistance of the front electrode and the semiconductor substrate 210.

Referring to FIG. 4, after the patterning process, the remaining mask layer 230 may be removed.

Thereafter, an anti-reflective coating (ARC) 260 may be formed on the emitter layer 220. In an embodiment, the ARC 260 may be formed using SiNₓ. Also, in an embodiment, the ARC 260 may have a refractive index of 2.0 to 2.3.

In an embodiment, the ARC 260 may be formed using a thermal growing process. In an embodiment, the ARC 260 may be formed using a thermal growing process at a temperature of about 900° C. In an embodiment, the thermal growing process for forming the ARC 260 may include a wet growing process and a dry growing process.

In another embodiment, the ARC 260 may be formed using a deposition process. In the present invention, the deposition process may be performed using a PECVD process. In this case, the deposition process may be performed using a deposition gas containing SiH₄.

Next, a front electrode 280 may be formed on a front surface of the semiconductor substrate 210, and a rear electrode 240 may be formed on a rear surface thereof, thereby completing the manufacture of a solar cell. In one embodiment, the front and rear electrodes 280 and 240 may be formed on the front and rear surfaces of the semiconductor substrate 210 using a printing process.

In the present invention, the front electrode 280 may be a silver (Ag) electrode having high electrical conductivity.

In the present invention, the rear electrode 240 of the semiconductor substrate 210 may be an aluminum (Al) electrode because an Al electrode has high conductivity and such a good affinity for silicon as to facilitate the bonding of the rear electrode 240 with the semiconductor substrate 210. Also, since aluminum is a Group 3A element, the aluminum rear electrode 240 may form a p+ layer (i.e., back surface field (BSF) layer) 244 at a bond surface between the aluminum rear electrode 240 and the semiconductor substrate 210, so that carriers cannot disappear but be collected at the rear surface of the semiconductor substrate 210 to enhance photoelectric conversion efficiency of the solar cell.

In the present invention, a process of forming the rear electrode 240 will be described in more detail. An aluminum layer 242 may be formed by coating aluminum on the rear surface of the semiconductor substrate 210, and annealed, thereby forming the BSF layer 244. Thus, an electric field may be formed in the rear surface of the semiconductor substrate 210, thereby reducing recombination in the rear surface of the semiconductor substrate 210.

In the present invention, the front and rear electrodes 280 and 240 may be formed in the reverse order.

According to the present invention, in a method of manufacturing the solar cell, the patterning of the front surface of the semiconductor substrate may include directly coating a corrosive emulsion on the mask layer using a screen printing process instead of complicated photolithography and etching processes so that a desired pattern can be formed using a relatively simple process.

As a result, the manufacture of the solar cell may be simplified, and manufacturing costs may be reduced, so that the commercialization and mass production of solar cells can be expected.

Furthermore, according to the present invention, surface recombination and a serial resistance of an electrode and a substrate may be reduced using a selective emitter, thereby improving photoelectric conversion efficiency.

It will be apparent to those skilled in the art that various modifications can be made to the above-described exemplary embodiments of the present invention without departing from the spirit or scope of the invention. Thus, it is intended that the present invention covers all such modifications provided they come within the scope of the appended claims and their equivalents.

1. A method of fabricating a solar cell, comprising:
implanting impurities of a second conductivity type opposite to a first conductivity type into a front surface of a semiconductor substrate of the first conductivity type to form an emitter layer;
forming a mask layer on the emitter layer;
patterning the mask layer by coating etching paste on a portion of the mask layer where a front electrode will be formed;
implanting high-concentration impurities into the portion of the mask layer where the front electrode will be formed to form a heavily doped region;
removing the remaining mask layer;
forming an anti-reflective coating (ARC) on the emitter layer;
forming the front electrode on the front surface of the semiconductor substrate; and
forming a rear electrode on a rear surface of the semiconductor substrate.

2. The method of claim 1, wherein patterning the mask layer is performed by coating the etching paste using a printing process.

3. The method of claim 1, wherein the etching paste contains an acid etching medium.

4. The method of claim 1, wherein forming the mask layer is performed using a thermal growing process.

5. The method of claim 4, wherein forming the mask layer is performed using a thermal growing process at a temperature of about 900° C.

6. The method of claim 5, wherein the thermal growing process includes a wet growing process and a dry growing process.

7. The method of claim 1, wherein forming the mask layer is performed using a deposition process.

8. The method of claim 7, wherein the deposition process is performed using a plasma-enhanced chemical vapor deposition (PECVD) process.

9. The method of claim 7, wherein the deposition process is performed using a deposition gas containing monosilane (SiH₄).

10. The method of claim 1, wherein forming the ARC is performed using a thermal growing process.

11. The method of claim 10, wherein forming the ARC is performed using a thermal growing process at a temperature of about 900° C.

12. The method of claim 10, wherein the thermal growing process includes a wet growing process and a dry growing process.

13. The method of claim 1, wherein forming the ARC is performed using a deposition process.

14. The method of claim 13, wherein the deposition process is performed using a PECVD process.

15. The method of claim 13, wherein the deposition process is performed using a deposition gas containing SiH₄.

16. The method of claim 1, wherein the ARC contains SiNₓ.

17. The method of claim 1, wherein the ARC has a refractive index of 2.0 to 2.3.

18. The method of claim 1, wherein forming the front and rear electrodes on front and rear surfaces of the semiconductor substrate are performed using a printing process.

19. The method of claim 1, wherein the rear electrode of the semiconductor substrate is formed using aluminum (Al).

20. The method of claim 19, wherein forming the rear electrode of the semiconductor substrate comprises:
coating aluminum on the rear surface of the semiconductor substrate; and
forming a back-surface field (BSF) layer by annealing the aluminum.

21. A solar cell manufactured using the method according to claim 1.
